(19) United States
(12) Patent Application Publication
(10) Pub. No.: US 2024/0164079 A1
(43) Pub. Date: May 16, 2024

(54) ELECTRONIC COMPONENT ACCOMMODATION SYSTEM

(71) Applicant: Murata Manufacturing Co., Ltd., Nagaokakyo-shi (JP)

(72) Inventors: Nobuto YAMADA, Nagaokakyo-shi (JP); Yusuke MORI, Nagaokakyo-shi (JP); Norihito INAMURO, Nagaokakyo-shi (JP); Naoto IKEDA, Nagaokakyo-shi (JP)

(21) Appl. No.: 18/423,964

(22) Filed: Jan. 26, 2024

Related U.S. Application Data
(63) Continuation of application No. PCT/JP2022/021113, filed on May 23, 2022.

(30) Foreign Application Priority Data
Jul. 29, 2021 (JP) 2021-124486

(51) Int. Cl. H05K 13/00; G06K 19/077

(52) U.S. Cl. CPC H05K 13/0084; G06K 19/07773

(57) ABSTRACT

An electronic component accommodation system includes a first accommodation case including electronic components accommodated therein and a first RFID tag including information relating to the electronic components inputted thereto, and a second accommodation case including a plurality of the first accommodation case accommodated therein and a second RFID tag including information relating to the electronic components inputted thereto.

### CROSS REFERENCE TO RELATED APPLICATIONS

This application claims the benefit of priority to Japanese Patent Application No. 2021-124486 filed on Jul. 29, 2021 and is a Continuation Application of PCT Application No. PCT/JP2022/021113 filed on May 23, 2022. The entire contents of each application are hereby incorporated herein by reference.

### BACKGROUND OF THE INVENTION

### 1. Field of the Invention

The present invention relates to electronic component accommodation systems.

### 2. Description of the Related Art

Conventionally, in a component manufacturer manufacturing small electronic components such as a semiconductor chip and a capacitor chip, a plurality of manufactured electronic components are accommodated in a single container, transported and stored in a factory, and shipped to a manufacturer of assembled products together with the container. As a configuration of the container, a structure is known in which a carrier tape holding electronic components one by one is wound around a reel, a magazine in which electronic components are aligned and accommodated, and a bulk case and a bagging method in which the electronic components are accommodated in a loose state, i.e., in a bulk state (see, e.g., Japanese Unexamined Patent Application Publication No. 2005-324839). On the other hand, in order to perform manufacturing management of articles, a technology is known using a radio tag system in which an RFID tag is attached to an individual article to be managed and ID information preset in the RFID tag is read (see, e.g., Japanese Unexamined Patent Application Publication No. 2002-358494).

As the size of each of the electronic components is significantly reduced, in order to manage mass-produced electronic components, it is considered to provide a case for accommodating the electronic components as the management target. However, Japanese Unexamined Patent Application Publication Nos. 2005-324839 and 2002-358494 do not refer to the point of collectively managing a large number of electronic components accommodated in a plurality of cases. Therefore, there is room for improvement.

### SUMMARY OF THE INVENTION

Example embodiments of the present invention provide electronic component accommodation systems that each enable a hassle-free and accurate management when managing a large number of electronic components accommodated collectively in a plurality of cases.

An example embodiment of the present invention provides an electronic component accommodation system including a first accommodation case including electronic components accommodated therein and a first RFID tag including information relating to the electronic components inputted thereto, and a second accommodation case including a plurality of the first accommodation cases accommodated therein and a second RFID tag including information relating to the electronic components inputted thereto.

According to example embodiments of the present invention, it is possible to provide electronic component accommodation systems that each enable hassle-free and accurate management when managing a large number of electronic components accommodated collectively in a plurality of cases.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of electronic components and a bulk case according to an example embodiment of the present invention.

FIG. 2 is a schematic perspective view of an electronic component accommodation system according to an example embodiment of the present invention.

FIG. 3 is a schematic plan view of a configuration of a first RFID tag according to an example embodiment of the present invention.

FIG. 4 is a flowchart showing an example of an electronic component management process in a component manufacturer using an electronic component accommodation system according to an example embodiment of the present invention.

FIG. 5 is a block diagram showing a hardware configuration for managing electronic components of the component manufacturer.

FIG. 6 is a perspective view of an example of a method of reading an RFID tag in the component manufacturer.

FIG. 7 is a perspective view of an example of a method of reading an RFID tag of a bulk case picked from a storage location in the component manufacturer.

FIG. 8 is a perspective view of a case where RFID tags of a plurality of bulk cases stacked on a pallet are read at the time of shipment of the management process.

FIG. 9 is a perspective view of another method of reading an RFID tag at the time of shipment of the management process.

### DETAILED DESCRIPTION OF THE EXAMPLE EMBODIMENTS

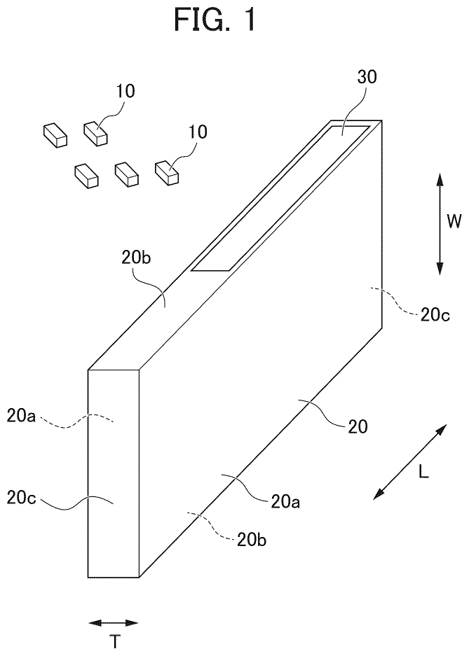

Hereinafter, example embodiments of the present invention will be described with reference to the drawings. FIG. 1 schematically shows a bulk case 20 defining and functioning as a first accommodation case and electronic components 10 accommodated in the bulk case 20. A plurality of electronic components 10 are directly accommodated in the bulk case 20.

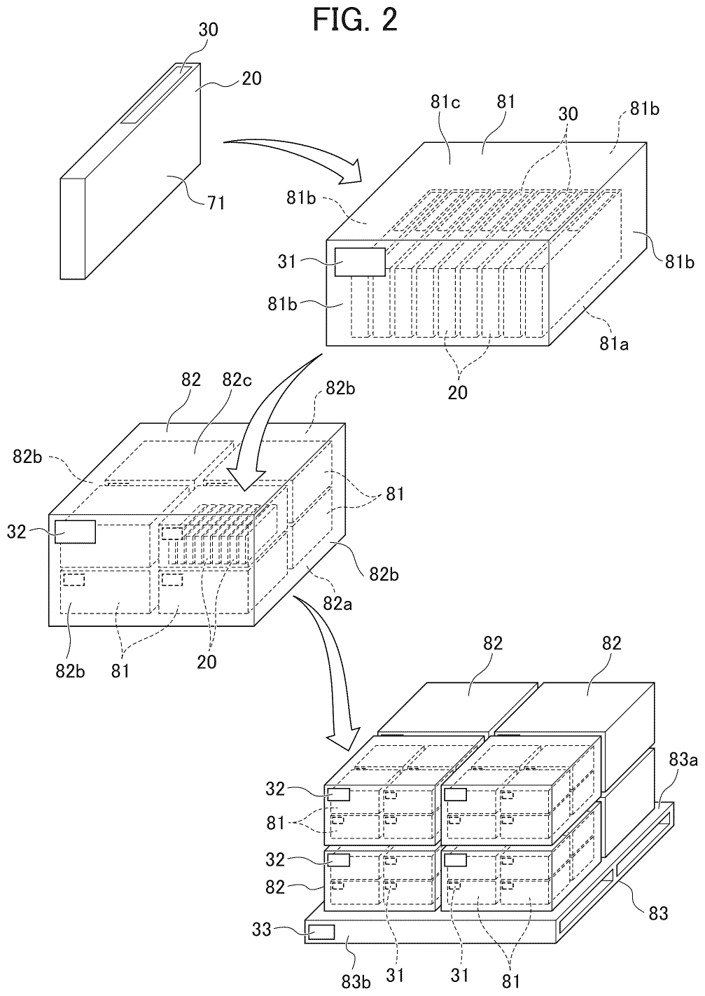

FIG. 2 schematically shows an electronic component accommodation system according to an example embodiment of the present invention. The electronic component accommodation system according to the present example embodiment includes the bulk case 20 in which the plurality of electronic components 10 are accommodated, exterior box 81 defining and functioning as a second accommodation case in which a plurality of bulk cases 20 to accommodate the plurality of electronic components 10 are accommodated, a conveyance outer box 82 defining and functioning as a third accommodation case in which a plurality of exterior boxes 81 are accommodated, and a pallet 83 defining and functioning as a fourth accommodation case in which a plurality of conveyance outer boxes 82 are accommodated.

The plurality of bulk cases 20 are accommodated in the exterior box 81, the plurality of exterior boxes 81 accommodating the plurality of bulk cases 20 are accommodated in one conveyance outer box 82, and the plurality of conveyance outer boxes 82 accommodating the plurality of exterior boxes 81 are accommodated in a state of being stacked on one pallet 83.

Each of the electronic components 10 according to the present example embodiment is, for example, a small rectangular or substantially rectangular parallelepiped electronic component having a longitudinal length of about 1.2 mm or less, such as a multilayer ceramic capacitor and an inductor.

As shown in FIG. 1, the bulk case 20 is a box body including a rigid body made of, for example, a resin and having a thin rectangular or substantially rectangular parallelepiped shape. In FIG. 1, L denotes a length direction of the bulk case 20, W denotes a width direction, and T denotes a thickness direction. The bulk case 20 includes a pair of main surfaces 20a opposed to each other in the thickness (T) direction, a pair of first end surfaces 20b opposed to each other in the width (W) direction, and a pair of second end surfaces 20c opposed to each other in the length (L) direction. The bulk case 20 accommodates, for example, several hundreds to several tens of thousands of electronic components 10 in a loose state, i.e., a bulk state. For example, a plurality of electronic components 10 are accommodated in the bulk case 20 from an openable and closable opening provided in one of the second end surfaces 20c.

Each of the bulk cases 20 includes a first RFID tag 30 having a planar shape. Each of the first RFID tags 30 includes an elongated adhesive sticker. Each of the first RFID tags 30 is attached to one end of one of the first end surface 20b of the bulk case 20. That is, each of the first RFID tags 30 is opposed to the first end surface 20b.

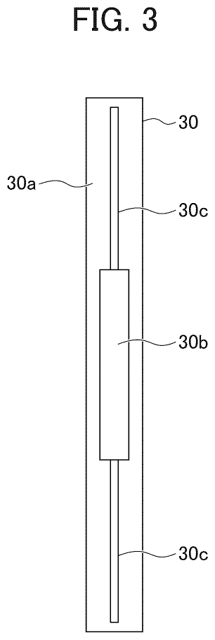

As shown in FIG. 3, each of the first RFID tags 30 according to the present example embodiment is a passive transponder including a rectangular or substantially rectangular sheet 30a made of resin defining and functioning as a base material, an RFID chip 30b made of a semiconductor integrated circuit, and a plurality of antennas 30c to communicate with an external device. The RFID chip 30b and the antenna 30c are attached to the sheet 30a. Each of the first RFID tags 30 may be, for example, of a type in which the RFID chip 30b and the antenna 30c are embedded in the sheet 30a. Alternatively, a power source may be provided. The RFID chip 30b includes, for example, a CPU, memory, a communication circuit, and the like.

Each of the first RFID tags 30 may be, for example, of a type in which memory cannot be rewritten (RO: Read Only), a type in which a single rewrite is possible (WORM: Write Once Read Many), or a type in which rewrite is possible (R/W: Read and Write). When the type of the first RFID tag 30 is RO or WORM, although information to be written is smaller than R/W, the cost is low.

Each of the first RFID tags 30 includes a unique number. Information related to the electronic components 10 is inputted to each of the first RFID tags 30. The information related to the electronic components 10 includes, for example, at least one of information related to the bulk case 20, production information including information related to the performance of the electronic components 10, and unique number information associated with the production information.

As shown in FIG. 2, each of the exterior boxes 81 accommodates the plurality of bulk cases 20. Each of the exterior boxes 81 is a rectangular or substantially rectangular parallelepiped box made of a material having appropriate rigidity, such as resin or cardboard, for example. Each of the exterior boxes 81 includes a bottom plate portion 81a, four lateral plate portions 81b, and a top plate portion 81c. For example, each of the exterior boxes 81 includes the top plate portion 81c which is openable and closable to accommodate the plurality of bulk cases 20 therein. The plurality of bulk cases 20 are accommodated in each of the exterior boxes 81 in a state in which the main surfaces 20a of the bulk cases 20 are aligned with each other, and the first RFID tags 30 on the upper sides of the bulk cases 20 are aligned in one direction (the rear side in FIG. 2) with the width (W) direction as the vertical direction. Several to several tens of bulk cases 20 are accommodated in the exterior box 81, for example. Each of the first RFID tags 30 is provided in the vicinity of the outer surface of the top plate portion 81c of the exterior box 81. Each of the first RFID tags 30 may be exposed to the outside.

Each of the exterior boxes 81 includes a second RFID tag 31 having a planar shape. Each of the second RFID tags 31 is, for example, a rectangular or substantially rectangular adhesive sticker. Each of the second RFID tags 31 has the same or substantially the same configuration as the first RFID tag 30 described above. That is, for example, each of the second RFID tags 31 is a passive transponder in which an RFID chip and an antenna are provided on a base sheet made of resin. For example, each of the second RFID tags 31 is attached to an upper portion of one end side in the lateral direction of one of the lateral plate portions 81b of each of the exterior boxes 81. That is, each of the second RFID tags 31 is opposed to the surface of one of the lateral plate portions 81b.

It is preferable that the plurality of bulk cases 20 are accommodated in the exterior box 81 such that each of the first RFID tags 30 is provided at a position opposite to the second RFID tag 31, and each of the first RFID tags 30 and the second RFID tag 31 are appropriately separated from each other. With such a configuration, each of the second RFID tags 31 is provided at a position not opposed to the first RFID tag 30. Each of the first RFID tags 30 and the second RFID tag 31 are preferably separated from each other by at least about 10 mm, for example. This reduces or prevents interference between each of the first RFID tags 30 and the second RFID tag 31. The second RFID tag 31 may be protected by applying a sticker to cover the surface of the second RFID tag 31.

Information related to the electronic components 10 is inputted to the second RFID tag 31. The information related to the electronic components 10 inputted to the second RFID tag 31 includes, for example, at least one of information related to the first RFID tag 30, production information including information related to the performance of the electronic components 10 inputted to the first RFID tag 30, and unique number information associated with the production information. The number of the bulk cases 20 of the exterior box 81 may be inputted to the second RFID tag 31. When individual information of the bulk case 20, for example, a case number or the like, is inputted to the second RFID tag 31 as information, positional information of the exterior box 81 indicating which bulk case 20 is provided and accommodated at which position of the exterior box 81 may also be inputted to the second RFID tag 31.

As shown in FIG. 2, each of the conveyance outer boxes 82 accommodates the plurality of exterior boxes 81 in a two-stage stacked state. Each of the conveyance outer boxes 82 includes, for example, a rectangular or substantially rectangular parallelepiped box made of a material having appropriate rigidity such as resin or cardboard. Each of the conveyance outer boxes 82 includes a bottom plate portion 82a, four lateral plate portions 82b, and a top plate portion 82c. For example, each of the conveyance outer boxes 82 includes the top plate portion 82c which is openable and closable to accommodate the plurality of exterior boxes 81 therein. The plurality of exterior boxes 81 are accommodated in each of the conveyance outer boxes 82 so that each of the second RFID tags 31 is provided adjacent to one side in one direction (front side in FIG. 2). Several to several tens of exterior boxes 81, for example, are accommodated in each of the conveyance outer boxes 82. Each of the second RFID tags 31 is provided in the vicinity of the outer surface of the lateral plate portion 82b of the conveyance outer box 82. Each of the second RFID tags 31 may be exposed to the outside.

Each of the conveyance outer boxes 82 includes a third RFID tag 32 having a planar shape. Each of the third RFID tags 32 has the same configuration as the first RFID tag 30 and the second RFID tag 31 described above. That is, for example, each of the third RFID tags 32 is a passive transponder in which an RFID chip and an antenna are provided on a base sheet made of resin. Each of the third RFID tags 32 is attached to an upper portion of one end side of one of the lateral plate portions 82b of each of the conveyance outer boxes 82. That is, each of the third RFID tags 32 is opposed to the surface of one of the lateral plate portions 82b. In order to reduce or prevent interference with the second RFID tag 31 and the first RFID tag 30, each of the third RFID tags 32 is preferably provided at a position not opposed to the second RFID tag 31 and the first RFID tag 30. Each of the third RFID tags 32 may be separated from the second RFID tag 31 by, for example, at least about 10 mm. The surface of each of the third RFID tags 32 may be covered with a sticker to protect the third RFID tag 32.

Information related to the electronic components 10 is inputted to the third RFID tag 32. The information related to the electronic components 10 inputted to the third RFID tag 32 includes, for example, at least one of information related to the first RFID tag 30, information related to the second RFID tag 31, production information including information related to the performance of the electronic components 10 inputted to the first RFID tag 30, and unique number information associated with the production information.

As shown in FIG. 2, the pallet 83 is a plate-shaped table carried by a forklift 65 described later. The plurality of conveyance outer boxes 82 are stacked on an upper surface 83a of the pallet 83. The plurality of conveyance outer boxes 82 are stacked on the pallet 83 so that each of the third RFID tags 32 is provided adjacent to one side in one direction (front side in FIG. 2). Several to tens of conveyance outer boxes 82, for example, are stacked on the pallet 83. Each of the conveyance outer boxes 82 is preferably loaded on the pallet 83 such that each of the third RFID tags 32 is exposed to the outside.

The pallet 83 includes a fourth RFID tag 33 having a planar shape. The fourth RFID tag 33 has the same or substantially the same configuration as the first RFID tag 30, the second RFID tag 31, and the third RFID tag 32. That is, for example, the fourth RFID tag 33 is a passive transponder in which an RFID chip and an antenna are provided on a resin sheet of a base material. The fourth RFID tag 33 is provided at one end of one lateral surface 83b of the pallet 83. That is, the fourth RFID tag 33 is opposed to the surface of the one side surface 83b. In order to reduce or prevent interference with the third RFID tag 32, the second RFID tag 31, and the first RFID tag 30, the fourth RFID tag 33 is preferably provided at a position not opposed to the third RFID tag 32, the second RFID tag 31, and the first RFID tag 30. The fourth RFID tag 33 may be separated from the third RFID tag 32 by, for example, at least about 10 mm. The fourth RFID tag 33 may be protected by applying a sticker to cover the surface of the fourth RFID tag 33.

Information related to the electronic components 10 is inputted to the fourth RFID tag 33. The information related to the electronic components 10 inputted to the fourth RFID tag 33 includes, for example, at least one of information related to the first RFID tag 30, information related to the second RFID tag 31, information related to the third RFID tag 32, production information including performance information related to the electronic components 10 inputted to the first RFID tag 30, and unique number information associated with the production information.

Next, an example of a management configuration of the electronic components 10 using the electronic component accommodation system according to the present example embodiment in a component manufacturer manufacturing the electronic components 10 will be described.

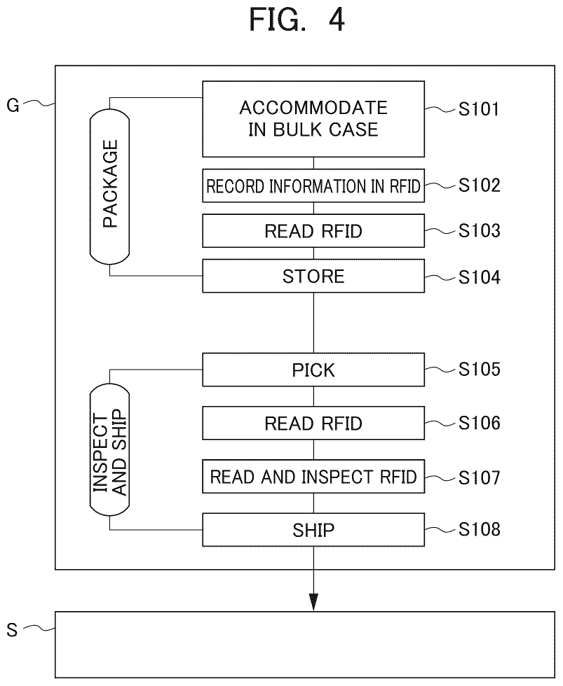

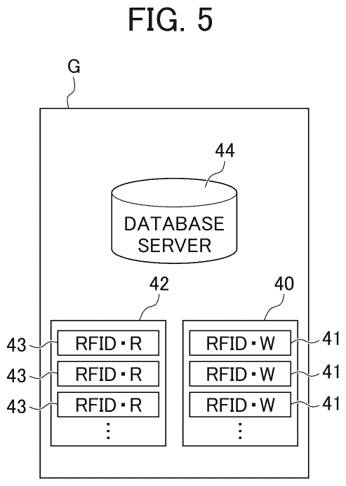

FIG. 4 shows an example of a process of the component manufacturer G manufacturing the electronic components 10 until the manufactured electronic components 10 are shipped. FIG. 5 shows a hardware configuration to manage the electronic components 10 in the component manufacturer G.

As shown in FIG. 5, the component manufacturer G includes a writer 40 capable of writing information relating to the component manufacturer G side to the first RFID tag 30 of the bulk case 20, a reader 42 to read information inputted to the first RFID tag 30 of the bulk case 20, and a database server 44. The writer 40 and the reader 42 may be integrated with each other as a reader/writer unit.

The writer 40 includes a plurality of RFID writers 41 capable of writing information in a non-contact manner. Each of the plurality of RFID writers 41 is provided at a predetermined position in the factory of the component manufacturer G. Each of the RFID writers 41 writes and inputs information read from the database server 44 to the first RFID tag 30 in a non-contact manner. The reader 42 includes a plurality of RFID readers 43 capable of reading information in a non-contact manner. Each of the plurality of RFID readers 43 is provided at a predetermined position in the factory of the component manufacturer G. The read information of each of the RFID readers 43 is inputted to the database server 44.

As shown in FIG. 4, the component manufacturer G performs a packaging process, an inspection process, and a shipping process of each of the electronic components 10. The component manufacturer G accommodates a large number of electronic components 10 manufactured in the factory in the bulk cases 20, conveys and stores them, and ships them to the user S. At the user S, for example, a process of incorporating the received electronic components 10 into electronic device sets is performed. Examples of the electronic device set include information terminal devices such as smartphones and tablets, and components such as electronic circuit boards of such devices. The flow for the electronic components 10 in the component manufacturer G and a manufacturer of assembled products S will now be described with reference to FIG. 4.

In the packaging process, a plurality of manufactured electronic components 10 are accommodated in the bulk cases 20 (step S101). In the first RFID tags 30 of the bulk cases 20 in which a plurality of electronic components 10 are accommodated, information relating to the accommodated electronic components 10 is inputted by a predetermined RFID writer 41 (step S102). Specifically, for example, the information relating to the electronic components 10 in the present example embodiment includes the lot number of the electronic components 10, the quantity of the electronic components 10 accommodated in the bulk cases 20, the production information including the information relating to the performance of the electronic components 10, the inspection number of the electronic components 10, the unique number of the bulk cases 20, and the like.

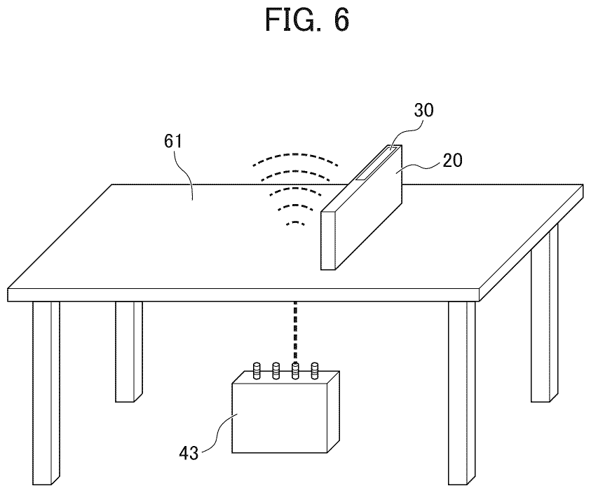

Next, information inputted to the first RFID tag 30 of one bulk case 20 is read by a predetermined RFID reader 43. For example, the unique number of the bulk case 20 is read (step S103). The information inputted to the first RFID tag 30 and the individual bulk cases 20 are associated with each other, and these pieces of information are stored in the database server 44. In order to read information of the first RFID tag 30, for example, as shown in FIG. 6, the first RFID tag 30 of the bulk case 20 placed on the table 61 is read by the RFID reader 43 placed on the table 61. The plurality of bulk cases 20 from which the information of each of the first RFID tags 30 is read are transported in the factory and stored in a predetermined storage location (step S104).

In the next inspection/shipment process, the bulk cases 20 are picked from the storage location (step S105), and the information recorded in each of the first RFID tags 30 is read (step S106).

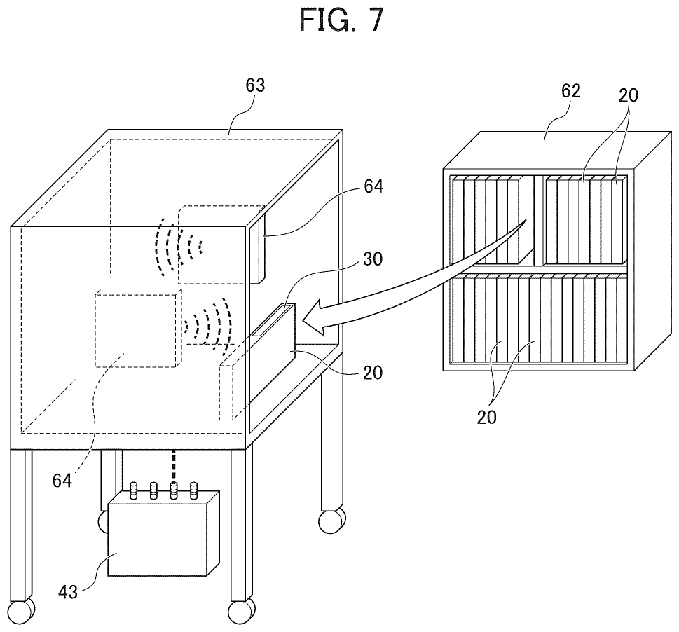

For example, as shown in FIG. 7, each of the bulk cases 20 is picked up from the storage place 62 such as a storage shelf and placed on a cart 63 to be conveyed, and the information recorded on each of the first RFID tags 30 is read by the RFID reader 43 on the cart 63 via a sensor 64. The RFID reader 43 is installed at an appropriate position of the cart 63. Thus, the information in which the bulk case 20 is going to be shipped is inputted to the database server 44. When the bulk case 20 is away from the readable distance of the RFID reader 43, the information recorded in the first RFID tag 30 may be read through the sensor 64 close to the bulk case 20.

The first RFID tag 30 of each of the bulk cases 20 is read by the RFID reader 43 such that the bulk cases 20 are inspected (step S107).

As shown in FIG. 2, a predetermined number of the plurality of bulk cases 20 that have been inspected are accommodated in one exterior box 81, the plurality of exterior boxes 81 are accommodated in one conveyance outer box 82, and further, the plurality of conveyance outer boxes 82 are stacked on the pallet 83 and shipped to the user S (step S108).

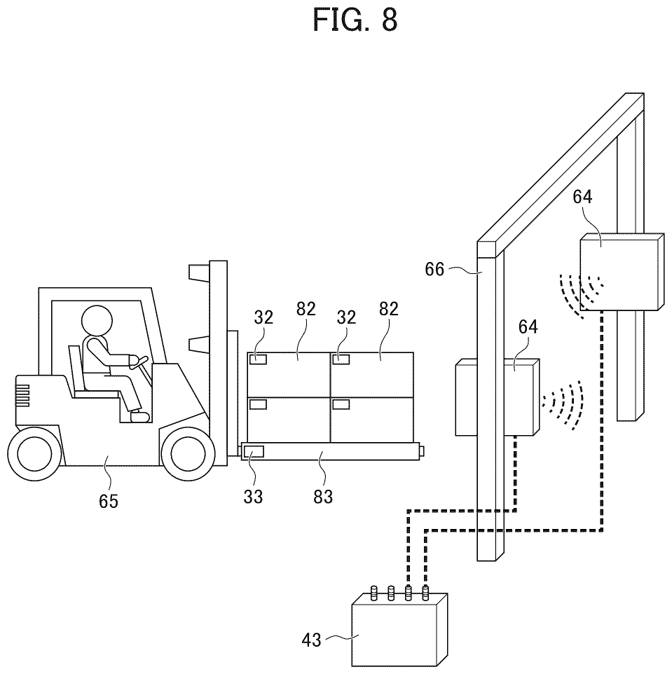

When the plurality of conveyance outer boxes 82 are stacked on the pallet 83, the pallet 83 is conveyed to and stacked on a conveyor such as, for example, a track by the forklift 65 as shown in FIG. 8. As the forklift 65 passes through the gate 66, the RFID reader 43 reads the fourth RFID tag 33 via a sensor 64 provided on the gate 66.

By reading the fourth RFID tag 33, information inputted to each of the plurality of third RFID tags 32 inputted to the fourth RFID tag 33 is read. In other words, the information inputted to each of the second RFID tags 31 and the first RFID tags 30 is read. By providing the fourth RFID tag 33 at a position not opposed to the third RFID tag 32, the RFID reader 43 can read only the fourth RFID tag 33 without interfering with each of the third RFID tags 32.

By reading the fourth RFID tag 33, all of the information relating to the large number of bulk cases 20 stacked on the pallet 83 and the electronic components 10 accommodated in the bulk case 20 is read. As described above, the information relating to the bulk cases 20 and the electronic components 10 accommodated in each of the bulk cases 20 include, for example, the lot number of the electronic components 10, the number of the electronic components 10 accommodated in each of the bulk cases 20, the production information including the information relating to the performance of the electronic components 10, the inspection number of the electronic components 10, the unique number of each of the bulk cases 20, and the like. By reading the fourth RFID tag 33 of the pallet 83 in this manner, the component manufacturer G can obtain and manage information relating to a large number of electronic components 10 shipped to the user S.

In the above-described example embodiment, by reading the fourth RFID tag 33 at the time of shipment, information is sequentially followed by the third RFID tag 32, the second RFID tag 31, and the first RFID tag 30 to finally obtain information relating to the electronic components 10 and the bulk cases 20. However, by omitting the fourth RFID tag 33 and reading the third RFID tags 32 of the conveyance outer boxes 82, information inputted to the first RFID tags 30 and the second RFID tags 31 may be read, such that the management may be performed based on the information.

Further, by omitting the fourth RFID tag 33 and the third RFID tags 32, and reading the second RFID tags 31 of the exterior boxes 81, information inputted to the first RFID tags 30 may be read, such that the management may be performed based on the information. In either case, since the information to be read is the information of the first RFID tags 30, it is the same information.

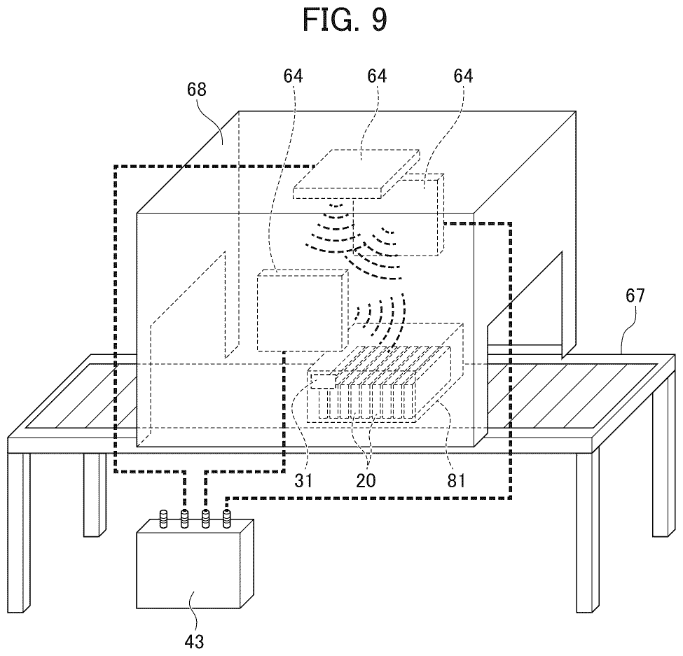

FIG. 9 shows an example of a configuration in which the second RFID tags 31 of the exterior boxes 81 are read. In FIG. 9, the RFID reader 43 reads the second RFID tag 31 via the sensor 64 provided in the gate 68 while the exterior box 81 being conveyed by a conveyance table 67 is conveyed in a tunnel-shaped gate 68. With such a configuration, the first RFID tags 30 of the plurality of bulk cases 20 of the exterior boxes 81 can be read.

Further, in the above example embodiment, at each timing at which the plurality of bulk cases 20 are accommodated in the exterior box 81, at which the plurality of exterior boxes 81 are accommodated in the conveyance outer boxes 82, and at which the plurality of conveyance outer boxes 82 are stacked in the pallet 83, information relating to the electronic components 10 and the bulk cases 20 are inputted to each of the second RFID tags 31, the third RFID tags 32, and the fourth RFID tags 33. However, information may be inputted to all of the second RFID tags 31 and the third RFID tags 32 at the same time as information is inputted to the fourth RFID tag 33 by stacking a plurality of conveyance outer boxes 82 on the pallet 83. As a result, information can be inputted to all of the second RFID tags 31 and the third RFID tags 32 by one information input operation, which greatly saves labor.

Further, in the above example embodiment, the information relating to the electronic components 10 and the bulk cases 20 is inputted to all of the second RFID tags 31, the third RFID tags 32, and the fourth RFID tags 33. However, only the unique numbers associated with the bulk cases 20 may be inputted to the second RFID tags 31, the third RFID tags 32, and the fourth RFID tags 33. In this case, when the second RFID tags 31, the third RFID tags 32, and the fourth RFID tags 33 are read, information relating to the electronic components 10 and the bulk cases 20 may be read based on the unique number of each of the first RFID tags 30.

Further, all of the information relating to the electronic components 10 and the bulk case 20 may be inputted to and stored in the database server 44, and only the unique numbers linked to the information may be written in the first RFID tags 30, the second RFID tags 31, the third RFID tags 32, and the fourth RFID tags 33. In this case, when a predetermined RFID reader 43 reads any one of the first RFID tags 30, the second RFID tags 31, the third RFID tags 32, and the fourth RFID tag 33, the predetermined RFID reader 43 accesses the database server 44 and reads information stored in the database server 44 in association with the unique number.

According to the example embodiment described above, the following advantageous effects are achieved. The electronic component accommodation system according to the present example embodiment includes the bulk case 20 defining and functioning as a first accommodation case that includes electronic components 10 accommodated therein and a first RFID tag 30 including information relating to the electronic components 10 inputted thereto, and the exterior box 81 defining and functioning as a second accommodation case that includes a plurality of the bulk cases 20 accommodated therein and a second RFID tag 31 including information relating to the electronic components 10 inputted thereto.

With such a configuration, by reading the second RFID tag 31 of the exterior box 81, it is possible to accurately manage a large number of electronic components 10 accommodated in each of the plurality of bulk cases 20 at once without any trouble.

In an electronic component accommodation system according to an example embodiment, it is preferable that the information relating to the electronic components 10 inputted to the first RFID tag 30 includes at least one of the information relating to the bulk cases 20, the production information including information relating to performance of the electronic components 10, and the unique number information associated with the production information.

With such a configuration, by reading the first RFID tag 30, it is possible to manage at least one of the information relating to the bulk case 20, the production information including the information relating to the performance of the electronic components 10, and the unique number information associated with the production information for each bulk case 20.

In an electronic component accommodation system according to an example embodiment, it is preferable that the information relating to the electronic components 10 inputted to the second RFID tag 31 includes at least one of the information relating to the first RFID tag 30, the production information including information relating to performance of the electronic components 10 inputted to the first RFID tag 30, and the unique number information associated with the production information.

With such a configuration, by reading the second RFID tag 31, it is possible to manage at least one of the information relating to the first RFID tag 30, the production information including the information relating to the performance of the electronic components 10 inputted to the first RFID tag 30, and the unique number information associated with the production information for each exterior box 81.

In an electronic component accommodation system according to an example embodiment, it is preferable that the first RFID tag 30 is opposed to the first end surface 20b of the bulk case 20, the bulk case 20 is provided such that the first RFID tag 30 is provided in a vicinity of an outer surface of the exterior box 81 or provided in the exterior box 81 so as to be exposed to outside, and the second RFID tag 31 is provided at a position not opposed to the first RFID tag 30.

With such a configuration, it is possible to shorten the communication distance at the time of reading and writing with respect to the first RFID tag 30 as much as possible and to perform stable communication because interference between the RFID tags hardly occurs.

In an electronic component accommodation system according to an example embodiment, it is preferable that the information inputted to the first RFID tag 30 and the information relating to the electronic components 10 are read by reading the second RFID tag 31 by the reader 42.

With such a configuration, it is possible to manage the information relating to the electronic components 10 accommodated in the plurality of bulk cases 20 in the exterior box 81 by reading the second RFID tag 31.

An electronic component accommodation system according to an example embodiment preferably further includes the conveyance outer box 82 defining and functioning as a third accommodation case that includes a plurality of the exterior boxes 81 accommodated therein and a third RFID tag 32 including information relating to the electronic components 10 inputted thereto.

With such a configuration, it is possible to perform accurate management without any trouble in collectively managing a large number of electronic components 10 accommodated in a plurality of bulk cases 20 by reading the third RFID tag 32 of the conveyance outer box 82.

In an electronic component accommodation system according to an example embodiment, it is preferable that the information relating to the electronic components 10 inputted to the third RFID tag 32 includes at least one of the information relating to the first RFID tag 30, the information relating to the second RFID tag 31, the production information including information relating to performance of the electronic components 10 inputted to the first RFID tag 30, and the unique number information associated with the production information.

With such a configuration, it is possible to manage at least one of the information relating to the first RFID tag 30, the information relating to the second RFID tag 31, the production information including the information relating to the performance of the electronic components 10 inputted to the first RFID tag 30, and the unique number information associated with the production information by reading the third RFID tag 32, for each conveyance outer box 82.

In an electronic component accommodation system according to an example embodiment, it is preferable that the second RFID tag 31 is opposed to a surface one of the lateral plate portions 81b of the exterior box 81, the exterior box 81 is provided such that the second RFID tag 31 is provided in the vicinity of an outer surface of the conveyance outer box 82 or provided in the conveyance outer box 82 so as to be exposed to outside, and the third RFID tag 32 is provided at a position not opposed to the first RFID tag 30 or the second RFID tag 31.

With such a configuration, it is possible to shorten the communication distance at the time of reading and writing with respect to the second RFID tag 31 as much as possible, and to perform stable communication because interference between the RFID tags hardly occurs.

In an electronic component accommodation system according to an example embodiment, it is preferable that the information inputted to the first RFID tag 30, the information inputted to the second RFID tag 31, and the information relating to the electronic components 10 are read by reading the third RFID tag 32 by the reader 42.

With such a configuration it is possible to manage the information relating to the electronic components 10 accommodated in the plurality of bulk cases 20 in the conveyance outer box 82, by reading the third RFID tag 32.

An electronic component accommodation system according to an example embodiment preferably further includes the pallet 83 defining and functioning as a fourth accommodation case that includes a plurality of the conveyance outer boxes 82 accommodated therein and the fourth RFID tag 33 including the information relating to the electronic components 10 inputted thereto.

With such a configuration, it is possible to accurately manage a large number of electronic components 10 accommodated in the plurality of bulk cases 20 collectively without any trouble, by reading the fourth RFID tag 33 of the pallet 83.

In an electronic component accommodation system according to an example embodiment, it is preferable that the information relating to the electronic components 10 inputted to the fourth RFID tag 33 includes at least one of the information relating to the first RFID tag 30, the information relating to the second RFID tag 31, the information relating to the third RFID tag 32, the production information including the information relating to performance of the electronic components 10 inputted to the first RFID tag 30, and the unique number information associated with the production information.

With such a configuration, it is possible to manage at least one of the information related to the first RFID tag 30, the information related to the second RFID tag 31, the information related to the third RFID tag 32, the production information including the information related to the performance of the electronic components 10 inputted to the first RFID tag 30, and the unique number information associated with the production information by reading the fourth RFID tag 33, for each pallet 83.

In an electronic component accommodation system according to an example embodiment, it is preferable that the third RFID tag 32 is opposed to a surface of one of the lateral plate portions 82b of the conveyance outer box 82, the conveyance outer box 82 is provided such that the third RFID tag 32 is provided in the vicinity of an outer surface of the pallet 83 or provided in the pallet 83 so as to be exposed to outside, and the fourth RFID tag 33 is provided at a position not opposed to any of the first RFID tag 30, the second RFID tag 31, or the third RFID tag 32.

With such a configuration, it is possible to shorten the communication distance at the time of reading and writing with respect to the third RFID tag 32, and to perform stable communication because interference between the RFID tags hardly occurs.

In an electronic component accommodation system according to an example embodiment, it is preferable that the information inputted to the first RFID tag 30, the information inputted to the second RFID tag 31, the information inputted to the third RFID tag 32, and the information relating to the electronic components 10 are read by reading the fourth RFID tag 33 by the reader 42.

With such a configuration, it is possible to manage the information relating to the electronic components 10 accommodated in the plurality of bulk cases 20 on the pallet 83 by reading the fourth RFID tag 33.

Although example embodiments of the present invention have been described above, the present invention is not limited to the above-described example embodiments, and modifications, improvements, and the like are included in the present invention as long as the scope of the present invention can be achieved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component accommodation system comprising:
a first accommodation case including electronic components accommodated therein and a first RFID tag including information relating to the electronic components inputted thereto; and
a second accommodation case including a plurality of the first accommodation cases accommodated therein and a second RFID tag including information relating to the electronic components inputted thereto.

2. The electronic component accommodation system according to claim 1, wherein the information relating to the electronic components inputted to the first RFID tag includes at least one of information relating to the first accommodation cases, production information including information relating to performance of the electronic components, and unique number information associated with the production information.

3. The electronic component accommodation system according to claim 1, wherein the information relating to the electronic components inputted to the second RFID tag includes at least one of information relating to the first RFID tag, production information including information relating to performance of the electronic components inputted to the first RFID tag, and unique number information associated with the production information.

4. The electronic component accommodation system according to claim 1, wherein
the first RFID tag is opposed to any one surface of the first accommodation case;
the first accommodation case is structured such that the first RFID tag is in a vicinity of an outer surface of the second accommodation case or in the second accommodation case so as to be exposed to outside; and
the second RFID tag is provided at a position not opposed to the first RFID tag.

5. The electronic component accommodation system according to claim 1, wherein the information inputted to the first RFID tag and the information relating to the electronic components are read by reading the second RFID tag via a reader.

6. The electronic component accommodation system according to claim 1, further comprising a third accommodation case that includes a plurality of the second accommodation cases accommodated therein and a third RFID tag including information relating to the electronic components inputted thereto.

7. The electronic component accommodation system according to claim 6, wherein the information relating to the electronic components inputted to the third RFID tag includes at least one of information relating to the first RFID tag, information relating to the second RFID tag, production information including information relating to performance of the electronic components inputted to the first RFID tag, and unique number information associated with the production information.

8. The electronic component accommodation system according to claim 6, wherein
the second RFID tag is opposed to any one surface of the second accommodation case;
the second accommodation case is structured such that the second RFID tag is in a vicinity of an outer surface of the third accommodation case or in the third accommodation case so as to be exposed to outside; and
the third RFID tag is provided at a position not opposed to the first RFID tag or the second RFID tag.

9. The electronic component accommodation system according to claim 6, wherein the information inputted to the first RFID tag, the information inputted to the second RFID tag, and the information relating to the electronic components are read by reading the third RFID tag via a reader.

10. The electronic component accommodation system according to claim 6, further comprising a fourth accommodation case including a plurality of the third accommodation cases accommodated therein and a fourth RFID tag including information relating to the electronic components inputted thereto.

11. The electronic component accommodation system according to claim 10, wherein the information relating to the electronic components inputted to the fourth RFID tag includes at least one of information relating to the first RFID tag, information relating to the second RFID tag, information relating to the third RFID tag, production information including information relating to performance of the electronic components inputted to the first RFID tag, and unique number information associated with the production information.

12. The electronic component accommodation system according to claim 10, wherein
the third RFID tag is opposed to one surface of the third accommodation case;
the third accommodation case is structured such that the third RFID tag is in a vicinity of an outer surface of the fourth accommodation case or in the fourth accommodation case so as to be exposed to outside; and
the fourth RFID tag is provided at a position not opposed to any of the first RFID tag, the second RFID tag, or the third RFID tag.

13. The electronic component accommodation system according to claim 10, wherein the information inputted to the first RFID tag, the information inputted to the second RFID tag, the information inputted to the third RFID tag, and the information relating to the electronic components are read by reading the fourth RFID tag via a reader.

14. The electronic component accommodation system according to claim 1, wherein each of the electronic components have a rectangular or substantially rectangular parallelepiped shape with a length of about 1.2 mm or less.

15. The electronic component accommodation system according to claim 1, wherein the first accommodation case includes a rigid body made of resin.

16. The electronic component accommodation system according to claim 1, wherein the first accommodation case accommodates several hundreds to tens of thousands of the electronic components.

17. The electronic component accommodation system according to claim 1, wherein the first RFID tag includes a rectangular or substantially rectangular sheet made of resin, an RFID chip including a semiconductor integrated circuit, and a plurality of antennas to communicate with an external device.

18. The electronic component accommodation system according to claim 1, wherein the second accommodation case is a rectangular or substantially rectangular box made of resin or cardboard.

19. The electronic component accommodation system according to claim 1, wherein the plurality of first accommodation cases accommodated in the second accommodation case include several to several tens of the first accommodation cases.

20. The electronic component accommodation system according to claim 1, wherein the first RFID tag and the second RFID tag are separated from each other by at least about 10 mm.
